(19) United States
(12) Patent Application Publication
(10) Pub. No.: US 2026/0287841 A1
(43) Pub. Date: Sep. 24, 2026

(54) OPTOELECTRONIC MODULE

(71) Applicant: PanelSemi Corporation, New Taipei City (TW)

(72) Inventor: Chin-Tang LI, New Taipei City (TW)

(21) Appl. No.: 19/572,047

(22) Filed: Mar. 19, 2026

Related U.S. Application Data
(60) Provisional application No. 63/774,445, filed on Mar. 19, 2025.
(60) Provisional application No. 63/778,110, filed on Mar. 26, 2025.

(51) Int. Cl. G02B 6/43; G02B 6/42; H10W 70/60; H10W 90/10

(52) U.S. Cl. CPC G02B 6/43; G02B 6/4239; G02B 6/424; G02B 6/4274; H10W 70/614; H10W 90/10

(57) ABSTRACT

An optoelectronic module includes a substrate structure, a planar circuit, a wiring layer, an optoelectronic component unit and an optical transmission component. The wiring layer is arranged on the edge portion of the substrate structure and electrically coupled to the planar circuit; the wiring layer at least defines a plurality of conductive pads. The optoelectronic component unit is arranged on the edge portion and electrically connected to conductive pads of the wiring layer, while the optoelectronic component unit is electrically coupled to the planar circuit through the conductive pads. The optical transmission component is optically coupled to the optoelectronic component unit. The optoelectronic component unit performs signal conversion between optical and electrical signals, wherein the electrical signals travel through the wiring layer between the planar circuit and the optoelectronic component unit, and the optical signals travel between the optical transmission component and the optoelectronic component unit.

### CROSS REFERENCE TO RELATED APPLICATIONS

This Non-provisional application which claims priority under 35 U.S.C. § 119(a) on Patent Application No(s). 63/774,445 filed in United States of America on Mar. 19, 2025, and on Patent Application No(s). 63/778,110 filed in United States of America on Mar. 26, 2025, the entire contents of which are hereby incorporated by reference.

### BACKGROUND

### Technology Field

The disclosure relates to an optoelectronic module, and more particularly to an optoelectronic module for optical component packaging.

### Description of Related Art

As optoelectronic modules require increasing data exchange with external devices, traditional electrical signal transmission interfaces have encountered bottlenecks, including limitations in transmission speed, electromagnetic interference issues, and high power consumption challenges. Consequently, the industry has begun adopting optical communication as an alternative solution. While optical communication offers advantages such as high transmission speed, strong interference resistance, and lower power consumption, integrating optical communication into optoelectronic modules still presents numerous technical challenges. In existing technologies, to improve optical-electrical coupling efficiency, additional optical components (such as lenses or mirrors) are typically employed for optical path adjustment. However, these solutions often increase the overall module size and manufacturing complexity. Meanwhile, traditional planar layouts also limit the spatial utilization efficiency of components, which is unfavorable for module miniaturization. Furthermore, the transmission distance between photoelectric conversion components and optical waveguides remains a critical issue, as longer transmission distances result in greater optical signal losses during transmission. Therefore, there is an urgent need in the industry for a novel optoelectronic module structure that can effectively reduce optical signal transmission paths, enhance optical-electrical coupling efficiency, while maintaining structural simplicity and ease of manufacturing.

### SUMMARY

One aspect of this disclosure is to provide an optoelectronic module and one or more exemplary embodiments thereof, which illustrate an optoelectronic module integrated with an optical coupling interface for coupling with external optical signals.

One aspect of this disclosure is to provide an optoelectronic module and one or more exemplary embodiments thereof, which demonstrate the integration of optical coupling interfaces that can effectively reduce the transmission distance of internal and external optical signals within the package structure, thereby significantly reducing optical signal losses.

Disclosed herein is an optoelectronic module comprising a substrate structure, a planar circuit, a wiring layer, an optoelectronic component unit, and an optical transmission component. The substrate structure defines a first surface and a second surface opposing to each other, and an edge portion connecting these two surfaces. The planar circuit is arranged on the first surface. The wiring layer is arranged on the edge portion and electrically coupled to the planar circuit; the wiring layer at least defines a plurality of conductive pads. The optoelectronic component unit, including one or more optoelectronic components, is arranged on the edge portion and electrically connected to conductive pads of the wiring layer, while one or ones of the optoelectronic components are electrically coupled to the planar circuit through the conductive pad or pads. The optical transmission component is optically coupled to the optoelectronic component. The optoelectronic component performs signal conversion between optical and electrical signals, wherein the electrical signals travel through the wiring layer between the planar circuit and the optoelectronic component, and the optical signals travel between the optical transmission component and the optoelectronic component.

In some embodiments, the edge portion includes a sidewall defined on the substrate structure, and the wiring layer is arranged on the sidewall.

In some embodiments, the edge portion includes a board disposed on the substrate structure, and the wiring layer is arranged on the board.

In some embodiments, the board is perpendicular to the planar circuit.

In some embodiments, the wiring layer faces the optical transmission component.

In some embodiments, the optoelectronic module further includes a semiconductor integrated circuit (IC) or packaged IC electrically coupled to the planar circuit.

In some embodiments, the semiconductor integrated circuit or the packaged IC further includes any or combination of an electronic integrated circuit (EIC), a photonic integrated circuit (PIC), a graphics processing unit (GPU), a central processing unit (CPU), an application-specific integrated circuit (ASIC), and a Switch.

In some embodiments, the substrate structure defines an accommodating recess, and the semiconductor integrated circuit (IC) or packaged IC is arranged in the accommodating recess.

In some embodiments, the semiconductor integrated circuit (IC) or packaged IC is arranged on either one of the first and second surfaces.

In some embodiments, the semiconductor integrated circuit (IC) or packaged IC includes a photonic integrated circuit coupled to the optoelectronic component.

In some embodiments, the edge portion includes a portion of the semiconductor integrated circuit (IC) or the packaged IC, and the wiring layer is arranged on the integrated circuit (IC) or the packaged IC.

In some embodiments, the wiring layer is arranged on a sidewall of an inner substrate of the semiconductor integrated circuit (IC) or the packaged IC.

In some embodiments, the substrate structure is a part of a semiconductor integrated circuit (IC) or packaged IC.

In some embodiments, the semiconductor integrated circuit or the packaged IC includes a photonic integrated circuit coupled to the optoelectronic component.

In some embodiments, the optoelectronic component defines an optical input/output direction parallel to the planar circuit.

In some embodiments, the optical input/output direction is perpendicular to the edge portion.

In some embodiments, the optoelectronic component defines an optical input/output direction being non-parallel to the planar circuit.

In some embodiments, the optoelectronic component defines an optical input/output direction being coplanar with the optical transmission component.

In some embodiments, the optical transmission component includes an optical fiber structure.

In some embodiments, the optical transmission component includes a waveguide structure.

In some embodiments, the optoelectronic module further includes an optical encapsulant encompassing the optoelectronic component and the optical transmission component.

In some embodiments, the encapsulant is a refractive index matching optical glue.

In some embodiments, the substrate structure includes silicon or silicon-containing material.

In some embodiments, the substrate structure includes a single substrate or a composite substrate formed of any one or a combination of silicon, glass, resin, ceramic, glass ceramic, and polyimide.

In some embodiments, the substrate structure further includes a single substrate or composite substrate formed of any one or a combination of BT (bismaleimide triazine) and FR4 (glass-reinforced epoxy laminate).

In some embodiments, the substrate structure includes a Low Temperature Co-fired Ceramic (LTCC) substrate, Medium Temperature Co-fired Ceramic (MTCC) substrate or High Temperature Co-fired Ceramic (HTCC) substrate.

In some embodiments, the substrate structure further includes a plurality of conductive vias; wherein the conductive vias electrically connect the planar circuit.

In some embodiments, one of the conductive vias is perpendicular to the planar circuit.

In some embodiments, one of the conductive vias communicates with the first and second surfaces.

In some embodiments, one of the conductive vias communicates with one of the first and second surfaces.

In some embodiments, the wiring layer is a part of one of the conductive vias.

In some embodiments, the optoelectronic module further includes a functional substrate and an alignment structure; wherein the substrate structure is configured on the functional substrate, and the alignment structure positions the optical transmission component.

In some embodiments, the optical transmission component is at least partially engaged with the alignment structure.

In some embodiments, the alignment structure includes one or more grooves.

In some embodiments, the groove or grooves are V-shaped or U-shaped.

In some embodiments, the functional substrate includes silicon or silicon-containing material.

In some embodiments, the functional substrate includes a single or composite substrate of any material or combination containing glass, resin, ceramic, glass ceramic, and polyimide (PI).

In some embodiments, the functional substrate further includes a single or composite substrate of any material or combination containing BT (bismaleimide triazine) and FR4 (glass-reinforced epoxy laminate).

In some embodiments, one or ones of the optoelectronic components includes at least one of a receiving device and an emitting device.

In some embodiments, the emitting device includes a Vertical-Cavity Surface-Emitting Laser (VCSEL).

In some embodiments, the emitting device includes an LED (Light-Emitting Diode) or an OLED (Organic Light-Emitting Diode).

In some embodiments, the emitting device is a packaged LED or a LED bare die.

In some embodiments, the optoelectronic component is a packaged optoelectronic component, which includes an internal substrate and one or more chips arranged on the internal substrate.

In some embodiments, the receiving device includes a Photodiode.

In some embodiments, the optoelectronic module further includes a light focusing structure located between the receiving device and the optical transmission component.

In some embodiments, the light focusing structure is a micro lens.

In some embodiments, the light focusing structure is a micro mirror.

In some embodiments, the light focusing structure is a Diffractive Optical Element (DOE).

In some embodiments, the optoelectronic components include multiple receiving devices and multiple emitting devices.

In some embodiments, the receiving devices and the emitting devices are arranged in separate zones.

In some embodiments, the receiving devices and the emitting devices are arranged alternately.

In some embodiments, the conductive pad defines a thickness not less than 2 μm.

In some embodiments, the wiring layer includes traces, and the conductive pad is disposed on the traces.

In some embodiments, the wiring layer further includes a patterned insulating layer, and the conductive pad or pads are defined by openings of the patterned insulating layer.

In some embodiments, the optoelectronic module further includes a connector housing covering at least part of the substrate structure, the planar circuit, the wiring layer, the optoelectronic component unit, and the optical transmission component.

In some embodiments, the connector housing has a pluggable structure.

The foregoing is merely illustrative and not intended to limit the present invention. In addition to the illustrative embodiments, examples, and features described above, other embodiments, examples, and features of the present invention can be clearly understood by referring to the drawings and the following detailed description.

### BRIEF DESCRIPTION OF THE DRAWINGS

FIG. 1A is a schematic view of an optoelectronic module according to a first embodiment of the present invention.

FIG. 1B is a schematic view of an optoelectronic module according to a second embodiment of the present invention.

FIG. 2A is a schematic view of an optoelectronic module according to a third embodiment of the present invention.

FIG. 2B is a schematic view of an optoelectronic module according to a fourth embodiment of the present invention.

FIG. 3A is a schematic view of an optoelectronic module according to a fifth embodiment of the present invention.

FIG. 3B is a schematic view of an optoelectronic module according to a sixth embodiment of the present invention.

FIG. 3C is an enlarged schematic view of the alignment structure of FIG. 3B.

FIG. 4A is a schematic view of an optoelectronic module according to a seventh embodiment of the present invention.

FIG. 4B is a schematic view of an optoelectronic module according to an eighth embodiment of the present invention.

FIG. 4C is a schematic view of an optoelectronic module according to a ninth embodiment of the present invention.

FIG. 5A is a schematic view of an optoelectronic module according to a tenth embodiment of the present invention.

FIG. 5B is a schematic view of an optoelectronic module according to an eleventh embodiment of the present invention.

FIG. 6 is a schematic view of an optoelectronic module according to a twelfth embodiment of the present invention.

FIG. 7 is a schematic view of an optoelectronic module according to a thirteenth embodiment of the present invention.

FIG. 8A is a schematic view of an optoelectronic module according to a fourteenth embodiment of the present invention.

FIG. 8B is an enlarged schematic view of FIG. 8A.

FIG. 9A is a schematic view of an optoelectronic module according to a fifteenth embodiment of the present invention.

FIG. 9B is an enlarged schematic view of FIG. 9A.

FIG. 10 is a schematic view of an optoelectronic module according to a sixteenth embodiment of the present invention.

FIG. 11A is a schematic view of an optoelectronic module according to a seventeenth embodiment of the present invention.

FIG. 11B is a schematic view of an optoelectronic module according to an eighteenth embodiment of the present invention.

FIG. 12A is a schematic view of an optoelectronic module according to a nineteenth embodiment of the present invention.

FIG. 12B is a schematic view of an optoelectronic module according to a twentieth embodiment of the present invention.

FIG. 13A is a schematic view of a first application form of the optoelectronic module of the present invention.

FIG. 13B is a schematic view of a second application form of the optoelectronic module of the present invention.

FIG. 13C is a schematic view of the optoelectronic module of FIG. 13B after being covered with an optical encapsulant.

FIG. 14A is a schematic view of a third application form of the optoelectronic module of the present invention.

FIG. 14B is a schematic view of a fourth application form of the optoelectronic module of the present invention.

FIG. 14C is a schematic view of a fifth application form of the optoelectronic module of the present invention.

FIG. 15 is a schematic view of a process form of the present invention.

### DETAILED DESCRIPTION OF THE DISCLOSURE

The following description will refer to relevant drawings to explain the preferred embodiments according to this invention, wherein the same elements will be described using the same reference symbols.

The advantages, features, and implementation methods of the present invention will be clearly explained in the following embodiments with reference to the drawings. However, the present invention may be embodied in various forms and should not be construed as being limited to the embodiments described herein. Rather, these embodiments are provided to make this specification thorough and complete, and to fully convey the scope of the disclosure to those skilled in the art. The scope of the present invention should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being “connected” to another element, it may be “directly or indirectly mechanically connected” to, or “electrically connected” to the other element, and one or more intervening elements may be present therebetween. It is to be understood that in this specification, the terms “include” or “comprise” specify the stated features, integers, steps, operations, elements and/or components, but do not preclude the presence or addition of one or more other features, integers, steps, operations, elements and/or components, or any combination thereof. The term “and/or” or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which the present invention pertains. Further, terms, including those defined in commonly used dictionaries, should be interpreted as having meanings consistent with their meaning in the context of the relevant art and will not be interpreted in an idealized or overly rigorous sense unless explicitly defined herein.

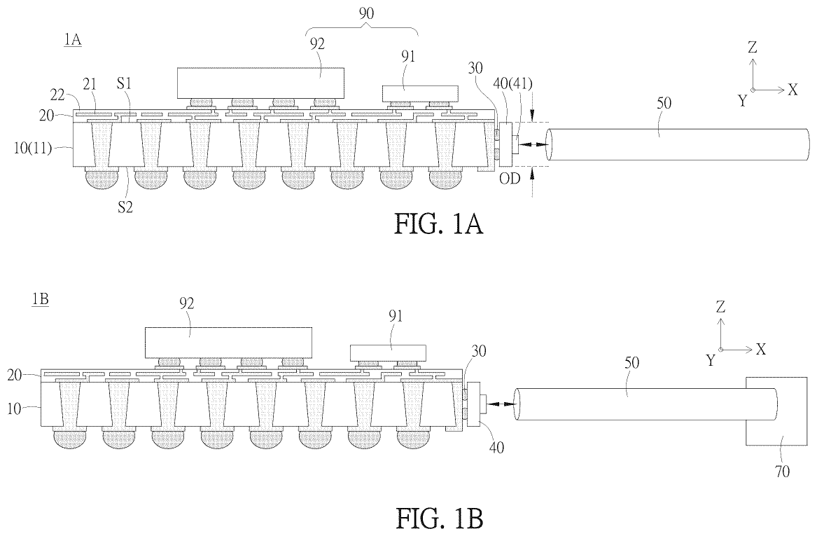

Referring to FIG. 1A, a first embodiment of the optoelectronic module 1A of the present invention is shown, including: a substrate structure 10, a planar circuit 20, a wiring layer 30, an optoelectronic component unit 40, and an optical transmission component 50. The substrate structure 10 defines opposing first and second surfaces S1, S2, and an edge portion ED connecting the first and second surfaces S1, S2; the edge portion ED refers to the edge area of the substrate structure 10, including sidewalls, accommodating recesses, or other components combined at the edge; the substrate structure 10 includes a substrate layer 11, or may further include multiple homogeneous or heterogeneous substrate layers. The planar circuit 20 is arranged on the first surface S1 of the substrate structure 10, but this does not mean that the second surface S2 has no circuit arrangement; in some embodiments, the planar circuit 20 includes a circuit layer 21; in some embodiments, the planar circuit 20 includes one or more circuit layers 21 and one or more insulating layers 22 combined with the circuit layer(s) 21, therefore, the planar circuit 20 can be a single wiring layer or redistribution layer (RDL). In some embodiments, the planar circuit 20 can be passive or active circuitry, but regardless of whether the planar circuit is active or passive, it does not affect the active or passive components subsequently placed thereon. The wiring layer 30 is arranged on the edge portion ED of the substrate structure 10 and electrically coupled to the planar circuit 20; the wiring layer 30 defines at least multiple conductive pads 31. It is worth noting that the wiring layer 30 being electrically coupled to the planar circuit 20 means that the wiring layer 30 may be directly electrically connected to the planar circuit 20, or indirectly electrically connected to the planar circuit 20 through one or more intermediate conductive structures. The aforementioned intermediate conductive structures may include, but are not limited to, a planar circuit on another side, vertical conductive vias electrically connecting planar circuits on two sides, redistribution lines, or any combination thereof, such that the wiring layer 30 is electrically connected to the aforementioned planar circuit 20. The optoelectronic component unit 40, including one or more optoelectronic components 41, is arranged on the edge portion ED of the substrate structure 10 and electrically connected to one or more of the conductive pads 31 of the wiring layer 30; the optoelectronic component 41 in this embodiment is top-emitting. Although named as wiring layer, the wiring layer 30 is used to distinguish from other components rather than limiting its active or passive nature. The optical transmission component 50 is optically coupled to the optoelectronic component unit 40. The optoelectronic component unit 40 can perform optical and electrical signal conversion, such as electrical signals transmitted between the planar circuit 20 and the optoelectronic component unit 40 through the wiring layer 30, and optical signals transmitted between the optical transmission component 50 and the optoelectronic component unit 40. In some embodiments, a semiconductor integrated circuit unit 90 is arranged on the first or second surface S1, S2 of the substrate structure 10, coupled to the planar circuit 20. The semiconductor integrated circuit unit 90 includes a semiconductor integrated circuit (IC) or packaged IC; for example, an electronic integrated circuit (EIC) 92 or photonic integrated circuit (PIC) 91, but is not limited thereto; the photonic integrated circuit 91 is coupled to the optoelectronic component unit 40. In other words, the semiconductor integrated circuit unit 90 can be, or include, any one or combination of electronic integrated circuit (EIC), photonic integrated circuit (PIC), graphics processing unit (GPU), central processing unit (CPU), application-specific integrated circuit (ASIC), or switch. In some embodiments, an optoelectronic component of the optoelectronic component unit 40 defines a light input/output direction OD, the light input/output direction OD is parallel to the planar circuit 20, but is not limited thereto; for example, the light input/output direction OD can be non-parallel to the planar circuit 20. In some embodiments, the light input/output direction OD of the optoelectronic component unit 40 can further be coplanar with the optical transmission component 50, but is not limited thereto. In some embodiments, the optical transmission component 50 can be a fiber optic structure or a waveguide structure, but is not limited thereto.

In some embodiments, the optoelectronic component includes a Vertical-Cavity Surface-Emitting Laser (VCSEL), Light-Emitting Diode (LED) or Organic Light-Emitting Diode (OLED), such as a packaged LED or LED bare die, or Photodiode. When the optoelectronic component is a packaged optoelectronic component, it may further include an internal substrate and one or more chips arranged on the internal substrate.

In some embodiments, the substrate structure 10 includes silicon or silicon-containing materials, or may further include a single or composite substrate of any material or combination containing glass, resin, ceramic, glass-ceramic, and polyimide; in some embodiments, the substrate structure 10 further includes a single or composite substrate of any material or combination containing BT (bismaleimide triazine) or FR4 (glass-reinforced epoxy laminate). In some embodiments, the substrate structure 10 includes an LTCC, MTCC, or HTCC substrate.

In some embodiments, the substrate structure 10 further includes multiple conductive vias 32; these conductive vias 32 are electrically connected to the planar circuit 20. In some embodiments, one or more of these conductive vias 32 communicate with the first and second surfaces S1, S2 as through-holes, but this does not preclude embodiments with blind holes, for example, where one or more of these conductive vias communicate with either one of the first and second surfaces S1, S2.

In some embodiments, the first surface and/or the second surface of the substrate structure may further be provided with external electrical connection structures for electrically connecting to external components, a package substrate, a circuit board, or other modules. The aforementioned external electrical connection structures may include conductive pads, bumps, solder balls, solder joints, metal posts, or a combination thereof. The aforementioned external electrical connection structures may be disposed on the first surface S1, the second surface S2, or both.

In some embodiments, the wiring layer 30 can be a part of one of the conductive vias 32, for example, the conductive via 32 exposes conductive material through grinding, or the wiring layer 30 can be formed by creating grooves at the edge portion and filling them with corresponding conductive material. In some embodiments, the wiring layer 30 is directly arranged on the edge portion ED of the substrate structure 10. It should be noted that the scope of the edge portion ED is not limited to the sidewall of the substrate structure 10.

In some embodiments, the conductive pads 31 define a thickness of not less than 2 μm. In some embodiments, the wiring layer 30 includes traces, and the conductive pads are disposed on the traces. In some embodiments, the wiring layer further includes a patterned insulating layer, and the conductive pads are defined by openings of the patterned insulating layer. Furthermore, the conductive pads can undergo additional surface treatment processes.

The optoelectronic module 1B in FIG. 1B further includes an alignment structure 70 for positioning the optical transmission component 50, allowing the optical transmission component 50 to align with the optoelectronic component unit 40.

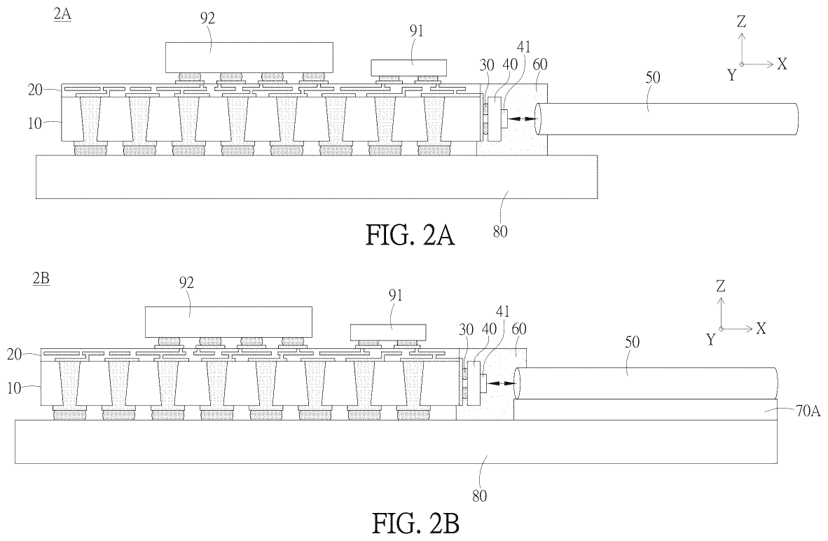

The optoelectronic module 2A in FIG. 2A further includes an optical encapsulant 60 encompassing the optoelectronic component unit 40 and the optical transmission component 50, where the optical encapsulant 60 is a refractive index matching optical glue. In some embodiments, the optoelectronic module 2A further includes a functional substrate 80, where both the substrate structure 10 and the optical transmission component 50 are arranged on the functional substrate 80. In some embodiments, the functional substrate 80 includes soft or hard materials, such as a single or composite substrate of any material or combination containing silicon or silicon-containing materials, glass, resin, ceramic, glass-ceramic, polyimide, BT (bismaleimide triazine) or FR4 (glass-reinforced epoxy laminate).

The optoelectronic module 2B in FIG. 2B further includes an alignment structure 70A for positioning the optical transmission component 50. The alignment structure 70A can be arranged between the optical transmission component 50 and the functional substrate 80, where in this embodiment, the alignment structure 70A is a component separate from the functional substrate 80.

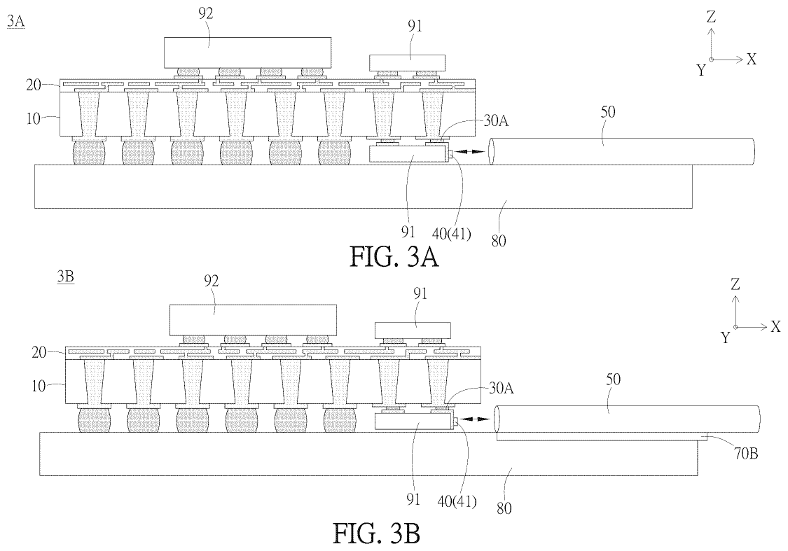

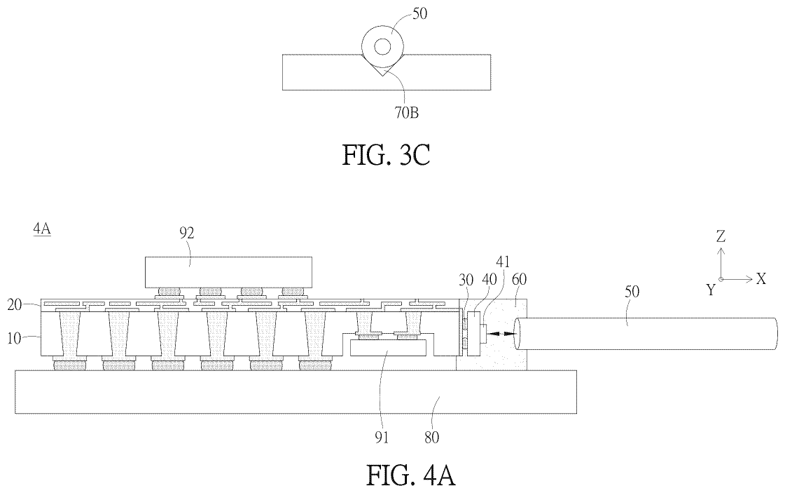

In the optoelectronic module 3A of FIG. 3A, the edge portion ED of the substrate structure 10 further covers part of the second surface S2 and components arranged on the second surface S2, where the photonic integrated circuit 91 is arranged on the second surface S2 of the substrate structure 10, and the wiring layer 30A is arranged on the edge portion ED of the photonic integrated circuit 91. Here, the wiring layer 30A can also be interpreted as being arranged on the edge portion of an internal substrate of the photonic integrated circuit 91; regardless of how the structure is interpreted, it is equivalent to the technical features disclosed herein; this also indicates that the substrate structure 10 can be part of a semiconductor integrated circuit (IC) or packaged IC.

The optoelectronic module 3B in FIG. 3B further includes an alignment structure 70B for positioning the optical transmission component 50. The alignment structure 70B can be arranged between the optical transmission component 50 and the functional substrate 80, where the alignment structure 70B can be a surface structure arranged on the corresponding surface of the functional substrate 80, either separate from or integrated into the functional substrate 80, for example, the alignment structure 70B includes one or more grooves, which can be V-shaped or U-shaped grooves, as shown in the V-shaped groove in FIG. 3C. Furthermore, in different embodiments, the alignment structures 70, 70A and 70B can all achieve optimal alignment with the optoelectronic component unit 40 through their thickness and arrangement with the functional substrate 80.

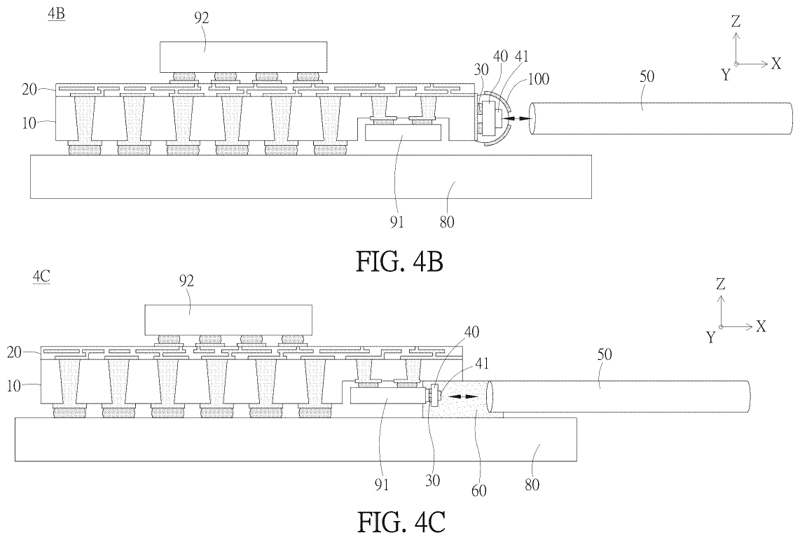

In the optoelectronic module 4A of FIG. 4A, the substrate structure 10 defines an accommodating recess SP, at least a portion of the semiconductor integrated circuit unit 90, such as the photonic integrated circuit 91, is arranged in the accommodating recess SP; here, the optoelectronic component unit 40 is configured on the edge portion ED of the substrate structure 10.

The optoelectronic module 4B in FIG. 4B further includes a light focusing structure located between the optoelectronic component unit 40 and the optical transmission component 50. In some embodiments, the light focusing structure can be a micro lens, a micro mirror, or a Diffractive Optical Element (DOE). The light focusing structure in this embodiment is represented by a micro mirror 100. The optical encapsulant 60 is replaced by a micro mirror 100, it should be noted that the micro mirror 100 is formed by coating a reflective layer on the micro lens and reserving a light passage opening.

In the optoelectronic module 4C, the optoelectronic component unit 40 is directly arranged on the side surface of the photonic integrated circuit 91; here, the wiring layer 30 is arranged on the side surface of the photonic integrated circuit 91, the optoelectronic component unit 40 is electrically connected through the wiring layer 30 to the circuit layer on one surface of the photonic integrated circuit 91, wherein this circuit layer can be equivalently considered as a planar circuit; alternatively, the optoelectronic module 4C can also be interpreted as being electrically coupled to the planar circuit 20.

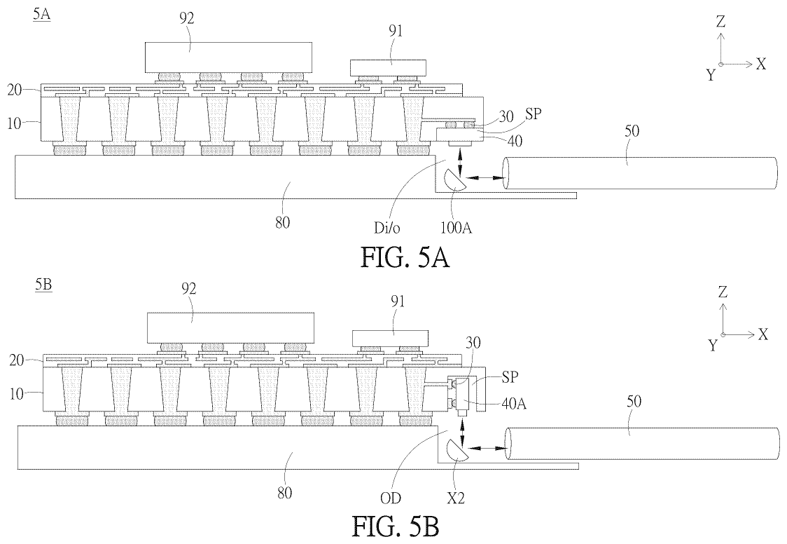

In the optoelectronic module 5A of FIG. 5A, the optoelectronic component unit 40 can be arranged in the accommodating recess SP of the substrate structure 10, its optoelectronic component is top-emitting, the wiring layer 30 is parallel to the planar circuit 20, and the light input/output direction OD is perpendicular to the planar circuit 20. The optoelectronic module 5A further includes a light focusing structure located between the optoelectronic component unit 40 and the optical transmission component 50. The light focusing structure in this embodiment is represented by a micro reflective element 100A configured with a specific reflection angle, which is a type of micro mirror.

In the optoelectronic module 5B of FIG. 5B, the optoelectronic component unit 40A can be arranged in the accommodating recess SP of the substrate structure 10, its optoelectronic component is side-emitting, the wiring layer 30 and the light input/output direction OD are perpendicular to the planar circuit 20.

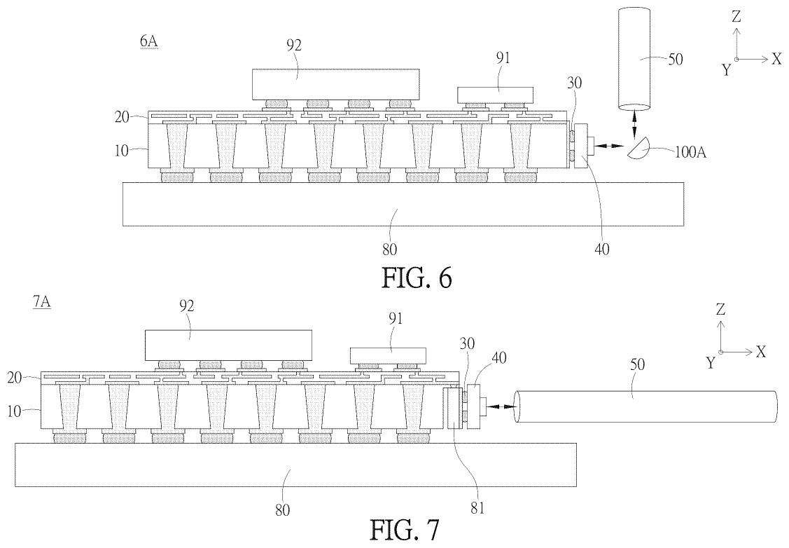

In the optoelectronic module 6A of FIG. 6, the optical transmission component 50 is arranged perpendicular to the planar circuit 20, and can also be combined with the micro reflective element 100A of the light focusing structure.

In the optoelectronic module 7A of FIG. 7, the edge portion ED of the substrate structure 10 can further include a board 81 that is independent from the substrate structure 10, the board 81 is perpendicular to the planar circuit 20, and the wiring layer 30 is arranged on the board 81.

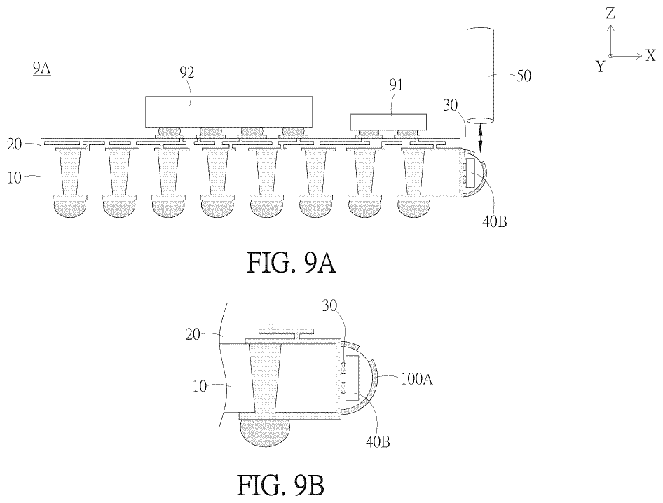

Referring to the optoelectronic module 9A in FIG. 9A, the optical transmission component 50 is arranged perpendicular to the planar circuit 20. The optoelectronic component unit 40B in FIG. 9A is top-emitting, coupled with a micro mirror 100 to form a light input/output direction OD perpendicular to the planar circuit 20 and aligned with the optical transmission component 50, as shown in FIG. 9B. In this embodiment, the optoelectronic component of the optoelectronic component unit 40B may be in a die form.

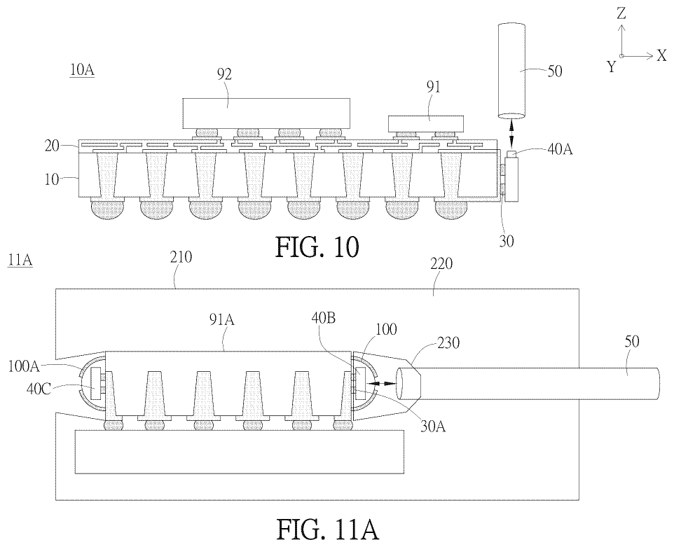

Referring to the optoelectronic module 10A in FIG. 10, the optical transmission component 50 is arranged perpendicular to the planar circuit 20. The optoelectronic component unit 40A in FIG. 10A is side-emitting, with its light input/output direction OD perpendicular to the planar circuit 20 and aligned with the optical transmission component 50.

The optical transmission component 50 mentioned above is a fiber optic structure, which includes one or multiple optical fibers.

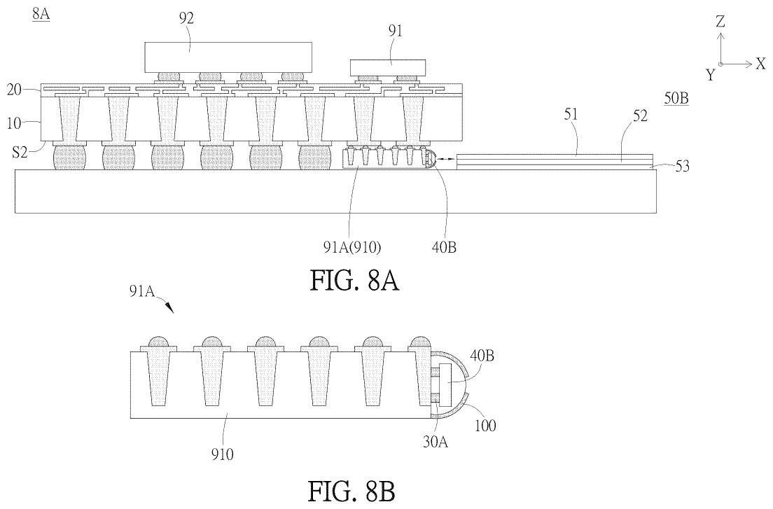

In the optoelectronic module 8A referred in FIGS. 8A and 8B, the optical transmission component 50B includes a waveguide component 51, a flexible substrate 52, and an adhesive material 53, arranged on the functional substrate 80. The optoelectronic component unit 40B is a top-emitting chip, which can be further coupled with a light focusing structure that is a micro mirror 100. The wiring layer 30B connected to the optoelectronic component unit 40B is arranged on the edge portion of a photonic integrated circuit 91A; in this embodiment, the photonic integrated circuit 91A has an internal substrate 910, and the wiring layer 30B is located on the edge portion of the internal substrate 910; similarly, the optoelectronic component unit 40B can be equivalently interpreted as being arranged on the edge portion of the substrate structure 10. In this embodiment, the photonic integrated circuit 91A is arranged on the second surface S2 of the substrate structure 10. In this embodiment, as in FIG. 8A, the optoelectronic component of the optoelectronic component unit 40B may be in a die form.

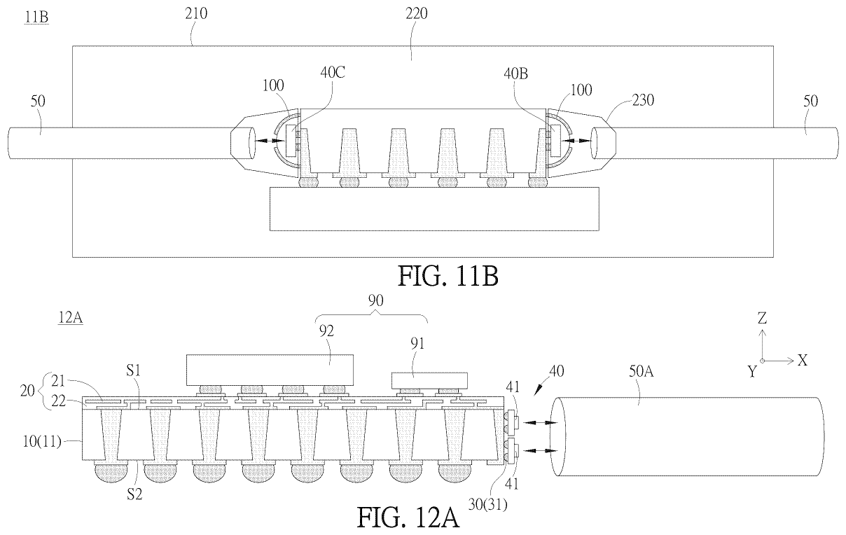

The optoelectronic module 11A in FIG. 11A further includes a connector housing 210 with an internal accommodating recess 220. The connector housing 210 covers at least portions of the substrate structure 10, planar circuit 20, wiring layer 30, at least one optoelectronic component unit 40B, and optical transmission component 50; in this embodiment, the optical transmission component 50 is a fiber optic structure, with a retaining member 230 configured at the port aligned with the optoelectronic component unit 40B, where the retaining member 230 can be optical encapsulant material, but is not limited thereto. In this embodiment, there are two optoelectronic component units 40B, 40C arranged on opposite edge portions of the substrate structure 10, providing optical transmission and reception functions respectively; here, the optoelectronic component unit 40B is combined with the optical transmission component 50, the fiber optic structure, for optical transmission, while the optoelectronic component unit 40C is reserved for subsequent optical reception. The connector housing 210 has a pluggable structure for connecting to other external equipment.

In the optoelectronic module 11B of FIG. 11B, the optoelectronic component unit 40C is further combined with the optical transmission component 50, the fiber optic structure, for optical reception.

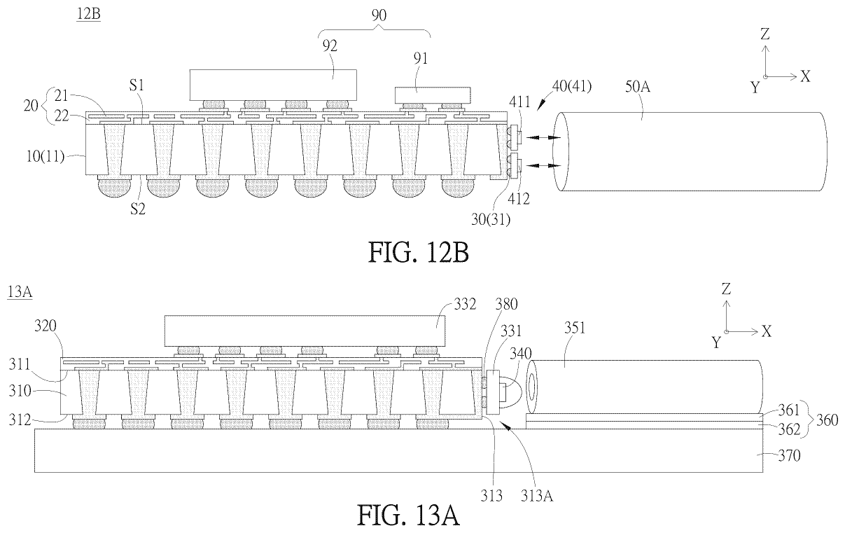

In the optoelectronic module 12A of FIG. 12A, the optoelectronic components 41 in the optoelectronic component unit 40 can include multiple receiving components and multiple emitting components. In this embodiment, taking multiple emitting components 41 as an example, all are aligned with the optical transmission component 50A. In this embodiment, the optical transmission component 50A may be a multi-channel optical transmission component.

In the optoelectronic module 12B of FIG. 12B, this embodiment takes at least one emitting component 411 and at least one receiving component 412 as examples, all aligned with the optical transmission component 50A. When there are multiple receiving and emitting components, the two types of optoelectronic components can be arranged in separate zones or in an alternating pattern.

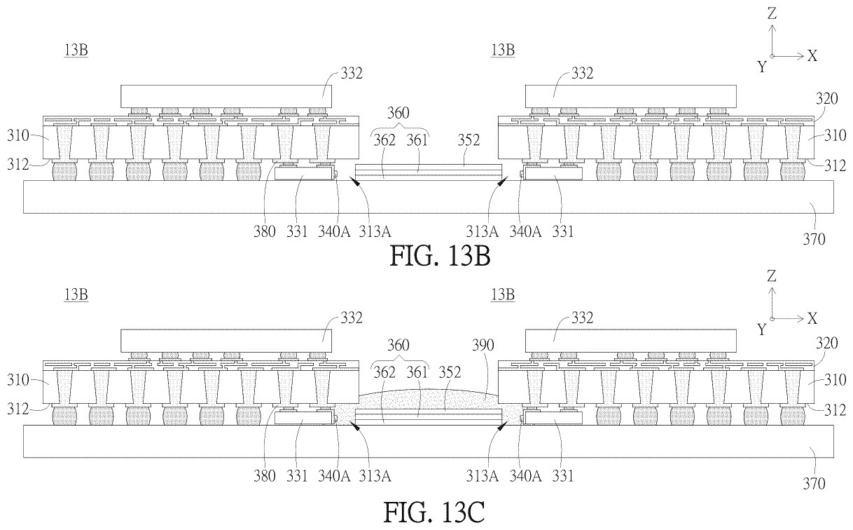

FIGS. 13A to 13C disclose application forms of the optoelectronic module 13A arranged on a functional substrate 370, which are briefly described as follows. FIG. 13A discloses that the optoelectronic component unit 340 combined with the photonic integrated circuit 331 is disposed on a sidewall 313 of the substrate structure 310. The substrate structure 310 further defines a corresponding first surface 311 and a second surface 312. The substrate structure 310 further defines an edge portion 313A, and the range of which covers the sidewall 313 and the regions of the first surface 311 and the second surface 312 adjacent to the sidewall 313. An optical fiber structure 351 is connected to the functional substrate 370 through a composite material 360. The composite material 360 includes a flexible substrate 361 and an adhesive material 362. The electronic integrated circuit 332 is a graphics processing unit (GPU) and is arranged on the first surface 311 of the substrate structure 310 through a planar circuit 320. The photoelectric element unit 340 and the photonic integrated circuit 331 are electrically coupled to the planar circuit 320 through a circuit layer 380. FIG. 13B discloses two optoelectronic modules 13B arranged in a mirror configuration. The two optoelectronic modules 13B share the same functional substrate 370, and optical coupling is achieved between the two optoelectronic modules 13B through a waveguide structure 352. Each optoelectronic component unit 340A combined with the photonic integrated circuit 331 is disposed on the second surface 312 of the substrate structure 310, but still falls within the edge portion 313A of the substrate structure 310. The waveguide structure 352 is connected to the functional substrate 370 through a composite material 360. The composite material 360 includes a flexible substrate 361 and an adhesive material 362. The electronic integrated circuit 332 is a GPU. FIG. 13C further discloses that the waveguide structure 352 and the optoelectronic component unit 340A of FIG. 13B are covered with an optical encapsulant 390.

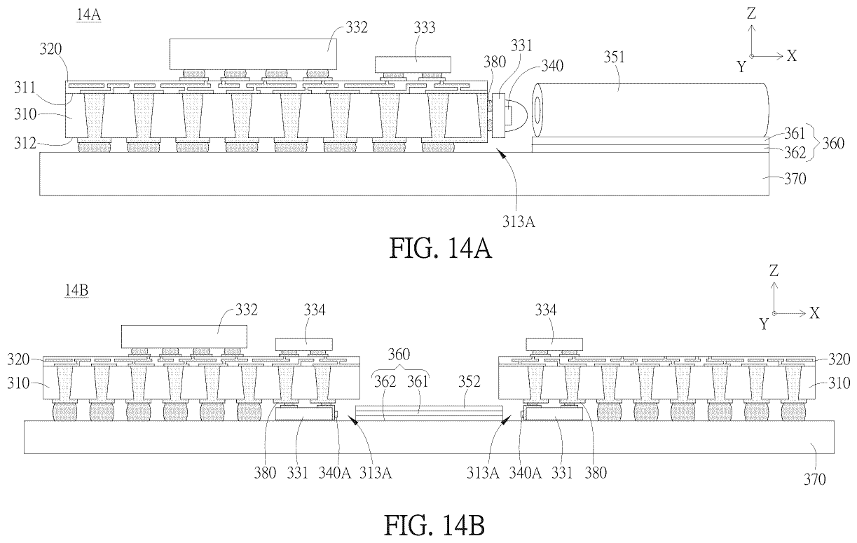

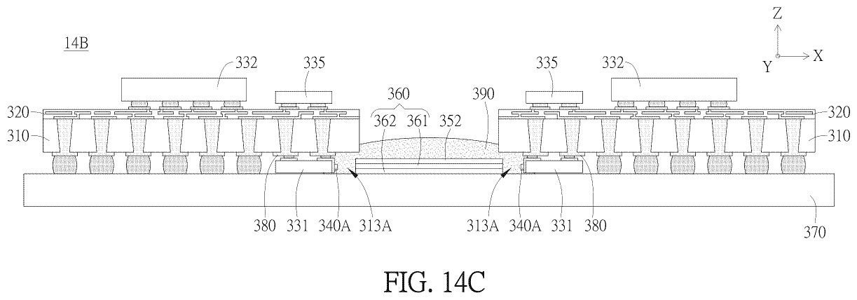

FIGS. 14A to 14C disclose application forms of the optoelectronic module, which are briefly described as follows. FIGS. 14A to 14C further extend the GPU application shown in FIGS. 13A to 13C to other possible embodiments, such as a central processing unit (CPU), an application-specific integrated circuit (ASIC), and a switch. The application embodiments are briefly described as follows. FIG. 14A discloses an optoelectronic module 14A, in which the optoelectronic component unit 340 combined with the photonic integrated circuit 331 is disposed on the substrate structure 310. An electronic integrated circuit 332, which is a graphics processing unit (GPU), is arranged on the first surface 311 of the substrate structure 310 through a planar circuit 320. A central processing unit 333 (CPU) is further provided and arranged on the substrate structure 310 through the planar circuit 320, thereby forming an application embodiment. FIG. 14B discloses another optoelectronic module 14B, in which the optoelectronic component unit 340 combined with the photonic integrated circuit 331 is disposed on the substrate structure 310 and is arranged in cooperation with an application-specific integrated circuit (ASIC) 334, thereby forming another application embodiment. The electronic integrated circuit 332 and the application-specific integrated circuit 334 may be arranged simultaneously or selectively. FIG. 14C discloses yet another application embodiment, in which the optoelectronic component unit 340 combined with the photonic integrated circuit 331 is disposed on the substrate structure 310. The electronic integrated circuit 332, which is a graphics processing unit (GPU), is arranged on the first surface 311 of the substrate structure 310 through a planar circuit 320. A switch 335 is further provided and arranged on the substrate structure 310 through the planar circuit 320. In addition, a waveguide structure 352 and a photoelectric element unit 340A are further covered with an optical packaging material 390, thereby forming yet another application embodiment. In some embodiments, the remaining structural configurations of FIGS. 14A to 14C may respectively refer to FIGS. 13A to 13C and will not be repeated herein.

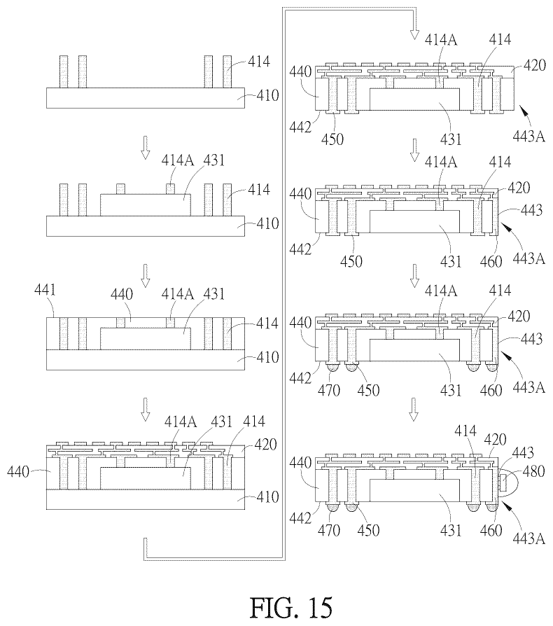

FIG. 15 illustrates another example of a fabrication process. First, conductive pillars 414, such as copper pillars (Cu pillars), are disposed on a carrier 410. A photonic integrated circuit chip 431 is then placed, and additional conductive pillars 414A are formed on a surface of the photonic integrated circuit chip 431. Next, an encapsulation material 440 is molded over the conductive pillars 414, 414A and the photonic integrated circuit chip 431 on the carrier 410. After subsequent surface treatment is performed on the first surface 441 of the encapsulation material 440, a planar circuit 420 is further disposed thereon, which is a redistribution line in this example. Thereafter, the carrier 410 is removed, and conductive pads 450 are disposed on the second surface 442 of the encapsulation material 440. In addition, part of the material at the side edge portion 443A is removed to form a sidewall 443, such that a portion of the conductive pillar 414 serves as a circuit layer 460 disposed at the side edge portion 443A. Next, conductive balls 470, such as solder balls, are provided at positions corresponding to the conductive pads 450. Finally, an optoelectronic component unit 490 is disposed and electrically connected to the circuit layer 460, so that the optoelectronic component unit 490 is electrically coupled to the planar circuit 420.

Based on the above description, it should be understood that various embodiments of the present invention have been described in the specification for illustrative purposes, and various modifications can be made without departing from the scope and spirit of the present invention. Therefore, the various embodiments of the present invention are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. An optoelectronic module, comprising:
a substrate structure defining a first surface and a second surface opposing to each other, and an edge portion connecting the first and second surfaces; wherein the substrate structure includes a substrate layer;
a planar circuit arranged on the first surface of the substrate structure;
a wiring layer arranged on the edge portion of the substrate structure and electrically coupled to the planar circuit; wherein the wiring layer at least defines a plurality of conductive pads;
an optoelectronic component unit, including one or more optoelectronic components, arranged on the edge portion of the substrate structure and connected to one or ones of the conductive pads of the wiring layer, wherein one or ones of the optoelectronic components are electrically coupled to the planar circuit through the conductive pad or pads; and
an optical transmission component optically coupled to the optoelectronic component;
wherein the optoelectronic component performs signal conversion between optical signals and electrical signals; the electrical signals are transmitted between the planar circuit and the optoelectronic component through the wiring layer, and the optical signals are transmitted between the optical transmission component and the optoelectronic component.

2. The optoelectronic module of claim 1, wherein the edge portion includes a sidewall defined on the substrate structure, and the wiring layer is arranged on the sidewall.

3. The optoelectronic module of claim 1, wherein the edge portion includes a board disposed on the substrate structure, and the wiring layer is arranged on the board.

4. The optoelectronic module of claim 1, wherein the wiring layer faces the optical transmission component.

5. The optoelectronic module of claim 1, further including a semiconductor integrated circuit (IC) or packaged IC electrically coupled to the planar circuit.

6. The optoelectronic module of claim 5, wherein the semiconductor integrated circuit or the packaged IC further includes any or combination of an electronic integrated circuit (EIC), a photonic integrated circuit (PIC), a graphics processing unit (GPU), a central processing unit (CPU), an application-specific integrated circuit (ASIC), and a Switch.

7. The optoelectronic module of claim 5, wherein the edge portion includes a portion of the semiconductor integrated circuit (IC) or the packaged IC, and the wiring layer is arranged on the integrated circuit (IC) or the packaged IC.

8. The optoelectronic module of claim 7, wherein the wiring layer is arranged on a sidewall of an inner substrate of the semiconductor integrated circuit (IC) or the packaged IC.

9. The optoelectronic module of claim 1, wherein the substrate structure is a part of a semiconductor integrated circuit (IC) or packaged IC.

10. The optoelectronic module of claim 9, wherein the semiconductor integrated circuit or the packaged IC includes a photonic integrated circuit coupled to the optoelectronic component.

11. The optoelectronic module of claim 1, wherein the optoelectronic component defines an optical input/output direction parallel to the planar circuit.

12. The optoelectronic module of claim 1, wherein the optoelectronic component defines an optical input/output direction being coplanar with the optical transmission component.

13. The optoelectronic module of claim 1, wherein the optical transmission component includes an optical fiber structure or a waveguide structure.

14. The optoelectronic module of claim 1, wherein the substrate structure includes silicon or silicon-containing material.

15. The optoelectronic module of claim 1, wherein the substrate structure includes a single or composite substrate of any material or combination containing glass, resin, ceramic, glass ceramic, and polyimide (PI).

16. The optoelectronic module of claim 15, wherein the substrate structure further includes a single or composite substrate of any material or combination containing BT (bismaleimide triazine) and FR4 (glass-reinforced epoxy laminate).

17. The optoelectronic module of claim 15, wherein the substrate structure includes a Low Temperature Co-fired Ceramic (LTCC) substrate, Medium Temperature Co-fired Ceramic (MTCC) substrate or High Temperature Co-fired Ceramic (HTCC) substrate.

18. The optoelectronic module of claim 1, further including a functional substrate and an alignment structure; wherein the substrate structure is configured on the functional substrate, and the alignment structure positions the optical transmission component.

19. The optoelectronic module of claim 1, wherein one or ones of the optoelectronic components includes at least one of a receiving device and an emitting device.

20. The optoelectronic module of claim 1, wherein the conductive pad defines a thickness not less than 2 μm.
